(19) United States
(12) Patent Application Publication
(10) Pub. No.: US 2023/0309299 A1
(43) Pub. Date: Sep. 28, 2023

(54) MEMORY DEVICE AND METHOD OF FABRICATING THE SAME

(71) Applicant: MACRONIX International Co., Ltd., Hsinchu (TW)

(72) Inventor: Chin-Cheng Yang, Kaohsiung City (TW)

(73) Assignee: MACRONIX International Co., Ltd., Hsinchu (TW)

(21) Appl. No.: 17/702,559

(22) Filed: Mar. 23, 2022

(51) Int. Cl. H01L 27/11582; H01L 27/1157; H01L 27/11556; H01L 27/11524; H01L 27/11519; H01L 27/11565

(52) U.S. Cl. CPC H01L 27/11582; H01L 27/11519; H01L 27/11524; H01L 27/11556; H01L 27/11565; H01L 27/1157

(57) ABSTRACT

A memory device includes a dielectric substrate, an interlayer structure, a plurality of channel pillars, a plurality of charge storage structures, a plurality of slit structures and an assistance structure. The dielectric substrate includes an array region and an iso region aside the array region. The interlayer structure is disposed in the array region and the iso region. The channel pillars penetrate through the interlayer structure in the array region. The charge storage structures are disposed between the interlayer structure and the plurality of channel pillars. The slit structures are disposed between the plurality of channel pillars, penetrate through the interlayer structure in the array region, and divide the interlayer structure into a plurality of blocks. The assistance structure is arranged in the iso region. The assistance structure includes at least one dummy slit structure having an extension direction different from an extension direction of the plurality of slit structures.

### BACKGROUND

### Technical Field

The embodiment of the disclosure relates to a semiconductor device and a method of fabricating the same, and particularly, to a memory device and a method of fabricating the same.

### Description of Related Art

Since a non-volatile memory device (e.g., a flash memory) has the advantage that stored data does not disappear at power-off, it becomes a widely used memory device for a personal computer or other electronics equipment.

Currently, the flash memory array commonly used in the industry includes a NOR flash memory and a NAND flash memory. Since the NAND flash memory has a structure in which memory cells are connected together in series, degree of integration and area utilization thereof are better than those of the NOR flash memory. Thus, the NAND flash memory has been widely used in a variety of electronic products. Besides, to further enhance the degree of integration of the memory device, a three-dimensional NAND flash memory is developed. However, there are still some challenges associated with the three-dimensional NAND flash memory.

### SUMMARY

The embodiments of the disclosure provide a memory device, which may reduce asymmetric wafer warpage caused by uneven stress and avoid abnormal tool operation in subsequent processes.

An embodiment of the disclosure provides a memory device including a dielectric substrate, an interlayer structure, a plurality of channel pillars, a plurality of charge storage structures, a plurality of slit structures and an assistance structure. The dielectric substrate includes an array region and an iso region aside the array region. The interlayer structure is disposed in the array region and the iso region. The channel pillars penetrate through the interlayer structure in the array region. The charge storage structures are disposed between the interlayer structure and the plurality of channel pillars. The slit structures are disposed between the plurality of channel pillars, penetrate through the interlayer structure in the array region, and divide the interlayer structure into a plurality of blocks. The assistance structure is arranged in the iso region. The assistance structure includes at least one dummy slit structure, and the extension direction of the at least one dummy slit structure is different from an extension direction of the plurality of slit structures.

An embodiment of the disclosure provides a method of fabricating a memory device and includes the following steps. An interlayer structure is formed in an array region and an iso region of a dielectric substrate. A plurality of channel pillars are formed to penetrate through the interlayer structure in the array region. A replacement process is performed to replace a plurality of insulating layers of the interlayer structure with a plurality of gate conductive layers. A plurality of slit structures are formed between the plurality of channel pillars. The slit structures extend through the interlayer structure in the array region and divide the interlayer structure into a plurality of blocks. An assistance structure is formed in the iso region. The assistance structure comprises at least one dummy slit structure, and an extension direction of the at least one dummy slit structure is different from an extension direction of the plurality of slit structures.

Based on the above, by disposing the assistance structure, the embodiments of the disclosure may reduce asymmetric wafer warpage caused by uneven stress and avoid abnormal tool operation in subsequent processes.

### BRIEF DESCRIPTION OF THE DRAWINGS

FIG. 1A to FIG. 1J are top views showing a three-dimensional memory chip according to an embodiment of the disclosure.

FIG. 2 is an enlarged top view of a partial region of FIG. 1B.

FIG. 3A to FIG. 3L are schematic cross-sectional views showing a method of fabricating a three-dimensional memory device according to an embodiment of the disclosure.

FIG. 4A to FIG. 7B are partial top and cross-sectional views showing iso regions of several three-dimensional memory devices according to multiple embodiments of the disclosure. FIG. 4B is a cross-sectional view taken along a line I-I′ of FIG. 4A. FIG. 5B is a cross-sectional view taken along a line II-II′ of FIG. 5A. FIG. 6B is a cross-sectional view taken along a line III-III′ of FIG. 6A. FIG. 7B is a cross-sectional view taken along a line IV-IV′ of FIG. 7A.

### DESCRIPTION OF THE EMBODIMENTS

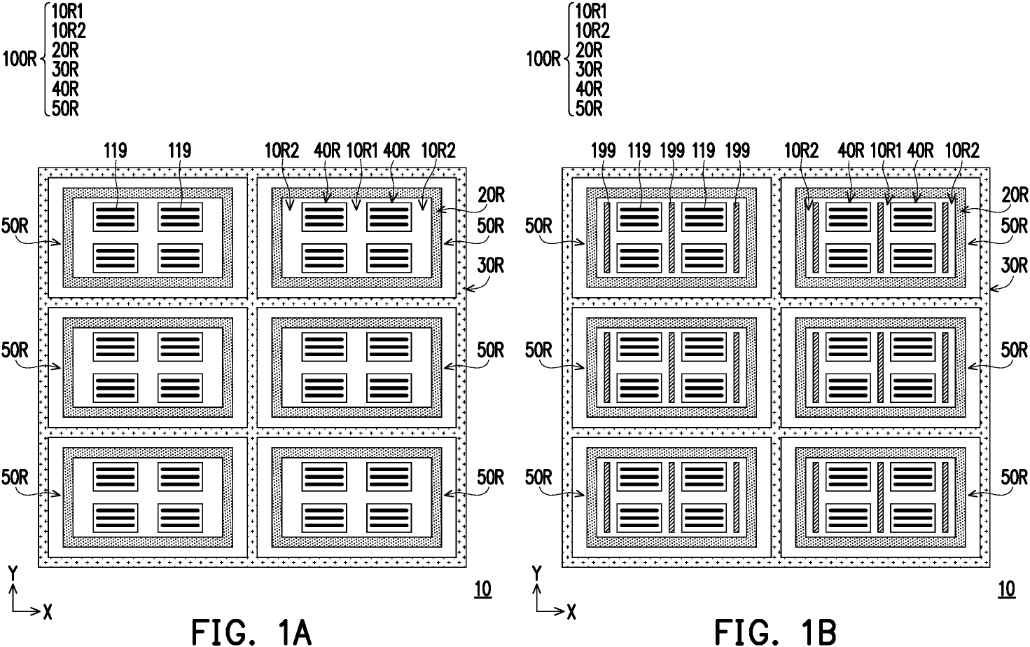

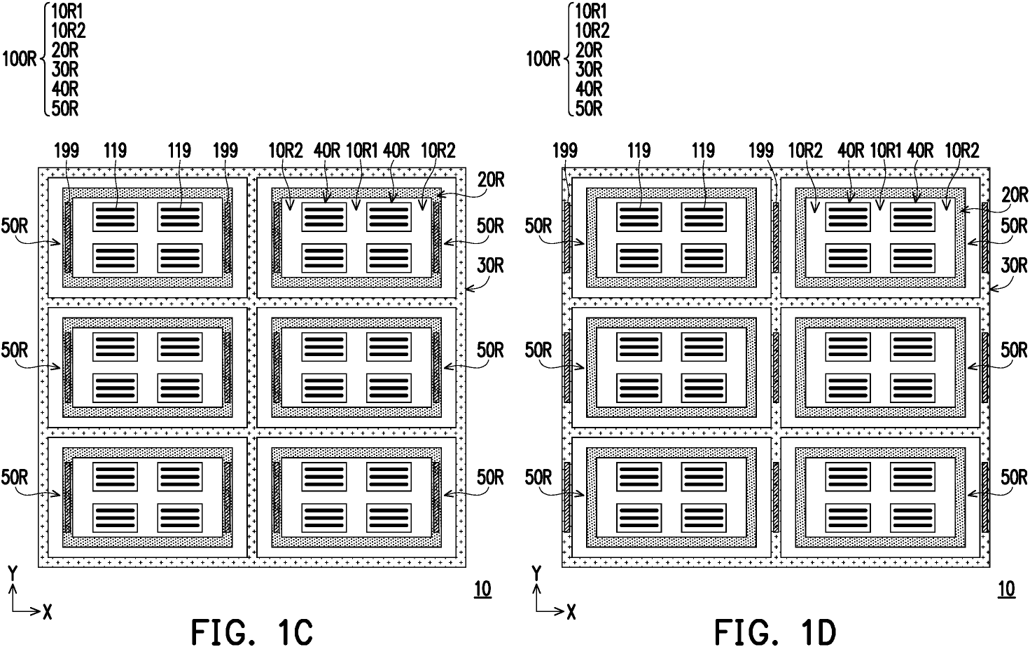

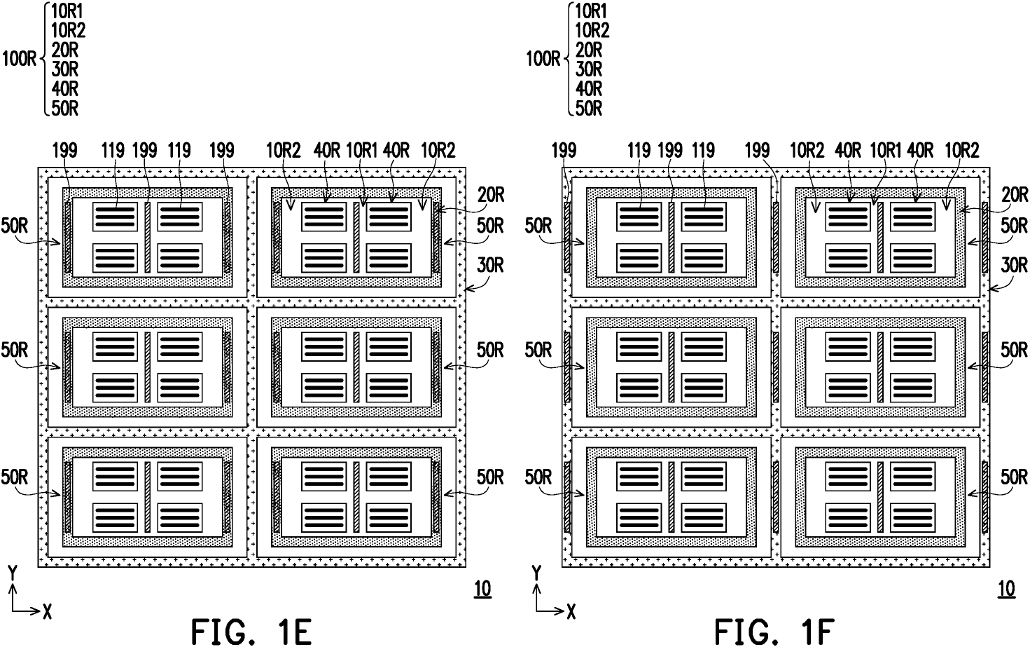

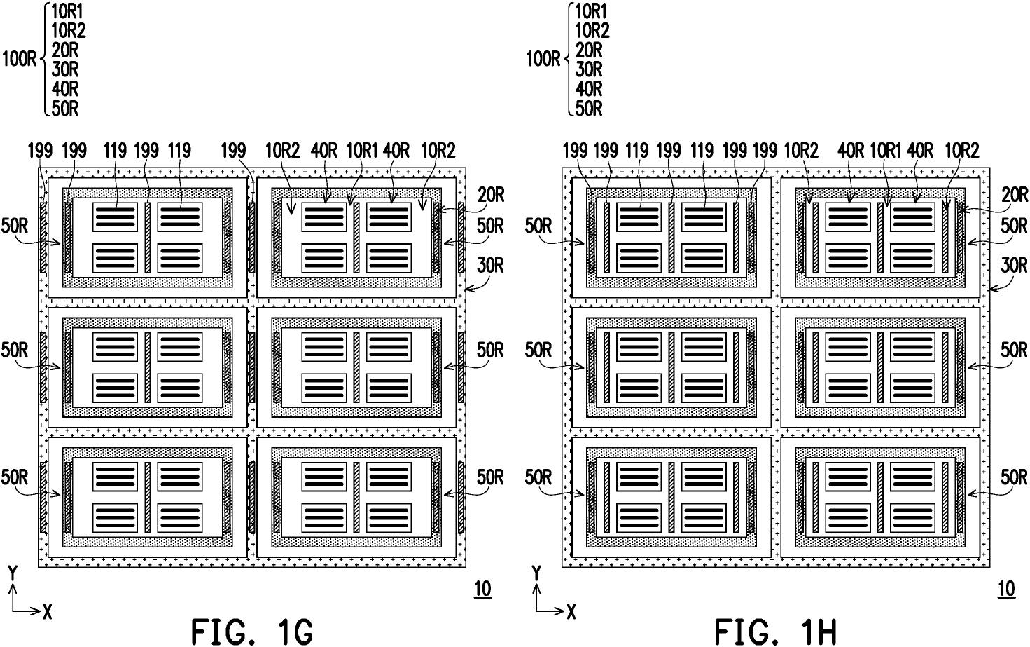

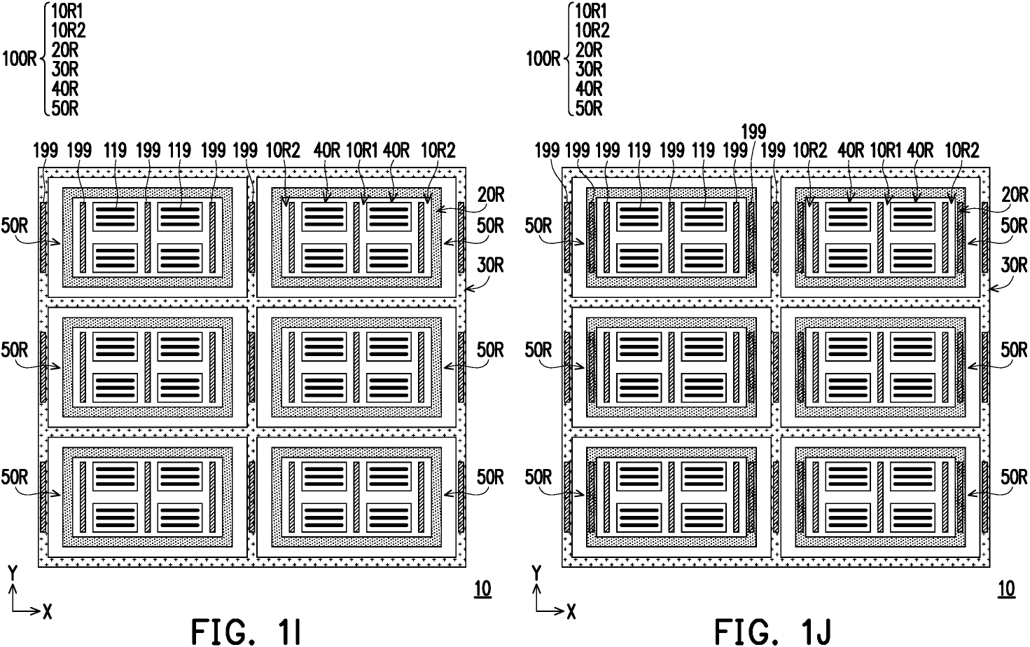

FIG. 1A to FIG. 1J are top views showing a three-dimensional memory chip according to an embodiment of the disclosure.

The placement and arrangement of the components of the memory device on the chip may cause issues such as uneven stress. For example, referring to FIG. 1A, the substrate 10 includes a plurality of slit structure 119. Since the slit structures 119 all extend along a single direction (for example, a horizontal direction, that is, the X direction), the stress of the substrate 10 in the X direction and the Y direction is uneven, and further induce wafer bow height X-Y bias. This may cause the wafer to warp asymmetrically, not to be gripped by the robot arm or to be damaged by the robot arm during transfer.

Referring to FIG. 1A to FIG. 1J, in an embodiment of the disclosure, a plurality of assistance structures 199 are formed to disperse or reduce the stress caused by the slit structures 119, so that the stress is more even in various directions (e.g., the X direction and the Y direction). Accordingly, issues such as asymmetric wafer warpage is avoided or reduced. In some embodiments, the extension direction of the assistance structures 199 is different from the extension direction of the slit structures 119. For example, the assistance structures 199 include dummy slit structures extending along the Y direction, to disperse or reduce the stress caused by the slit structure 119 extending in the X direction.

Referring to FIG. 1A to FIG. 1J, the assistance structures 199 may be disposed in the iso region 100R of the substrate 10. The substrate 10 has a plurality of scribe regions 30R. The scribe region 30R may divide the substrate 10 into a plurality of chip regions 50R. Each chip region 50R includes multiple block regions 40R. A memory cell array is to be formed in each block region 40R. A boundary region 10R1 is disposed between the block regions 40R. A seal ring region (or referred to as die sealing region) 20R is disposed in the substrate 10 between a pair of the block region 40R and the scribe region 30R. A boundary region 10R2 is disposed between the seal ring region 20R and the block region 40R. The iso region 100R may be the boundary region 10R1, 10R2, the seal ring region 20R, the scribe region 30R, or the region between these regions.

Referring to FIG. 1B to FIG. 1D, the assistance structures 199 are all formed at the same locations of the chip regions 50R, respectively. Referring to FIG. 1B, the assistance structures 199 are all formed in the boundary regions 10R1 and 10R2. Referring to FIG. 1C, the assistance structures 199 are all formed in the seal ring region 20R. Referring to FIG. 1D, the assistance structures 199 are all formed in the scribe region 30R.

Referring to FIG. 1E and FIG. 1F, the assistance structures 199 are formed at two locations of the chip regions 50R, respectively. Referring to FIG. 1E, the assistance structures 199 are all formed in the boundary region 10R1 between the block regions 40R and the seal ring region 20R. Referring to FIG. 1F, the assistance structures 199 are all formed in the boundary region 10R1 between the block regions 40R and the scribe region 30R.

Referring to FIGS. 1G to 1I, the assistance structures 199 are formed at three locations of the chip regions 50R, respectively. Referring to FIG. 1G, the assistance structures 199 are formed in the boundary region 10R1 between the block regions 40R, the seal ring region 20R and the scribe region 30R. Referring to FIG. 1H, the assistance structures 199 are formed in the boundary region 10R1 between the block regions 40R, the boundary region 10R2 between the block region 40R and the seal ring region 20R and the seal ring region 20R. Referring to FIG. 1I, the assistance structures 199 are formed in the boundary region 10R1 between the block regions 40R, the boundary region 10R2 between the block region 40R and the seal ring region 20R and the scribe region 30R.

Referring to FIG. 1J, the assistance structures 199 are formed at four locations of the chip regions 50R, respectively. For example, the assistance structures 199 are formed in the boundary region 10R1 between the block regions 40R, the boundary region 10R2 between the block region 40R and the seal ring region 20R, the seal ring region 20R, and the scribe region 30R.

Referring to FIGS. 1A to 1J, the composition, shape and size of the assistance structures 199 in each chip region 50R may be the same, similar or different.

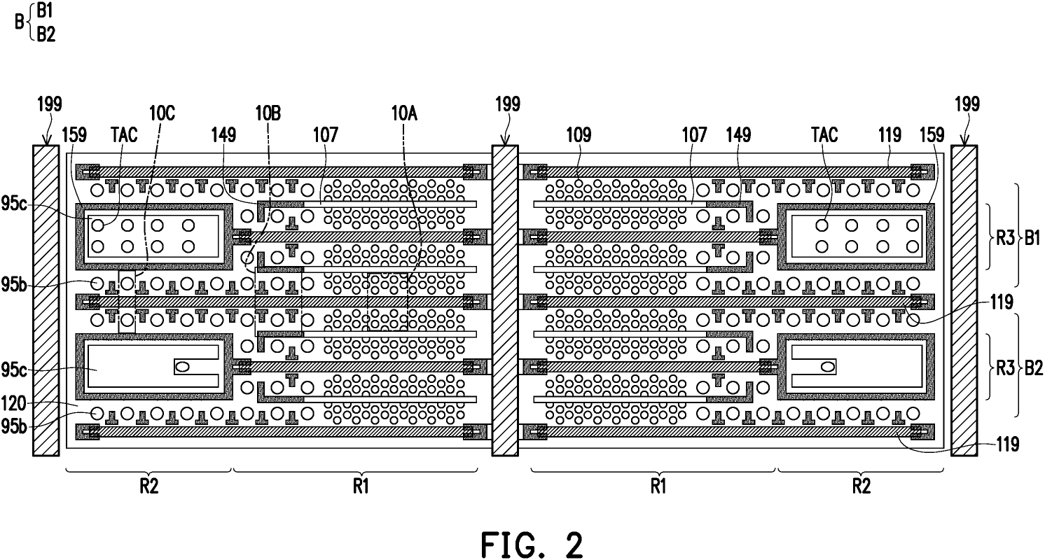

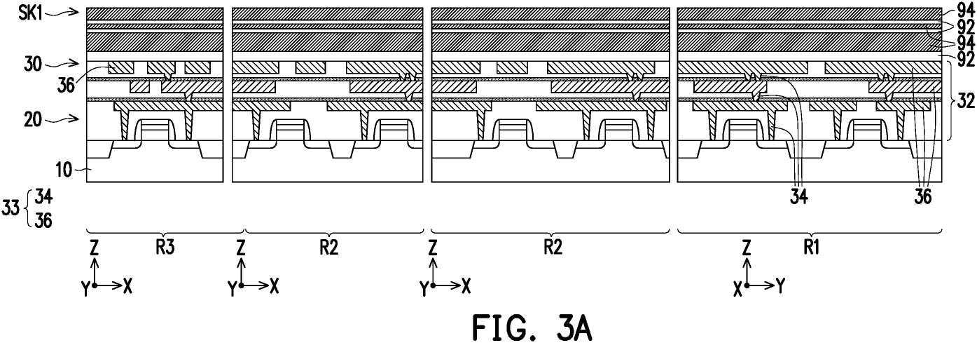

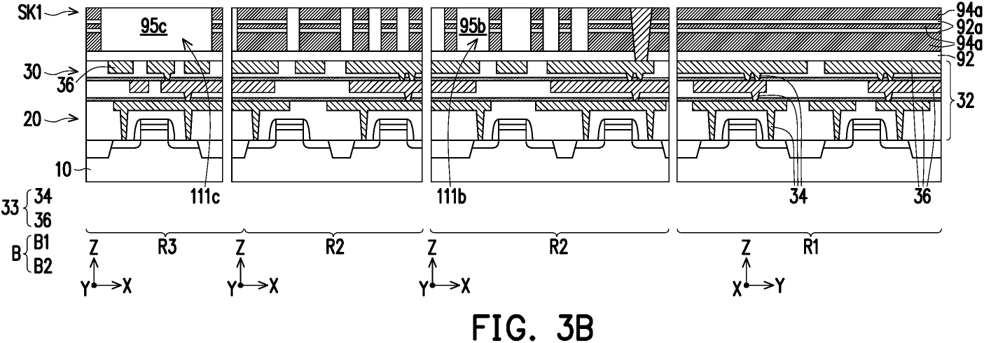

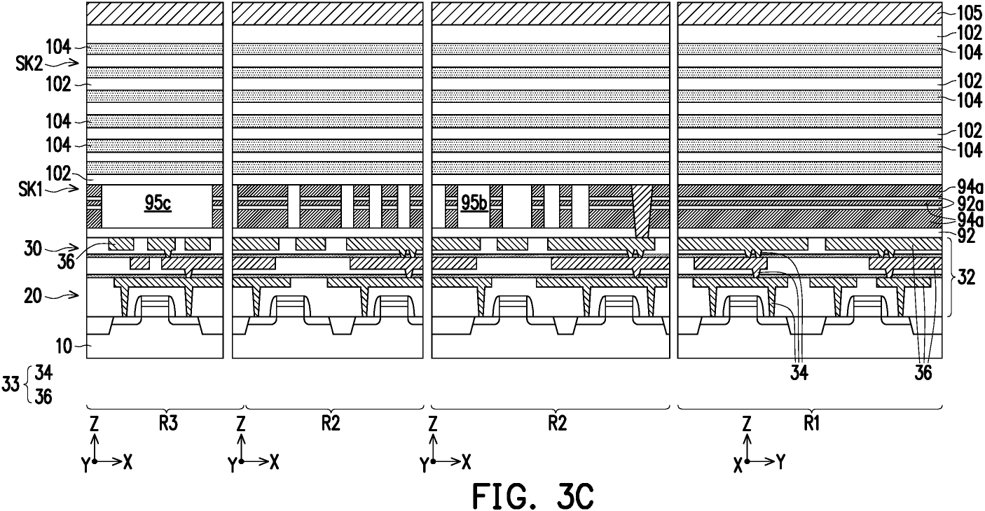

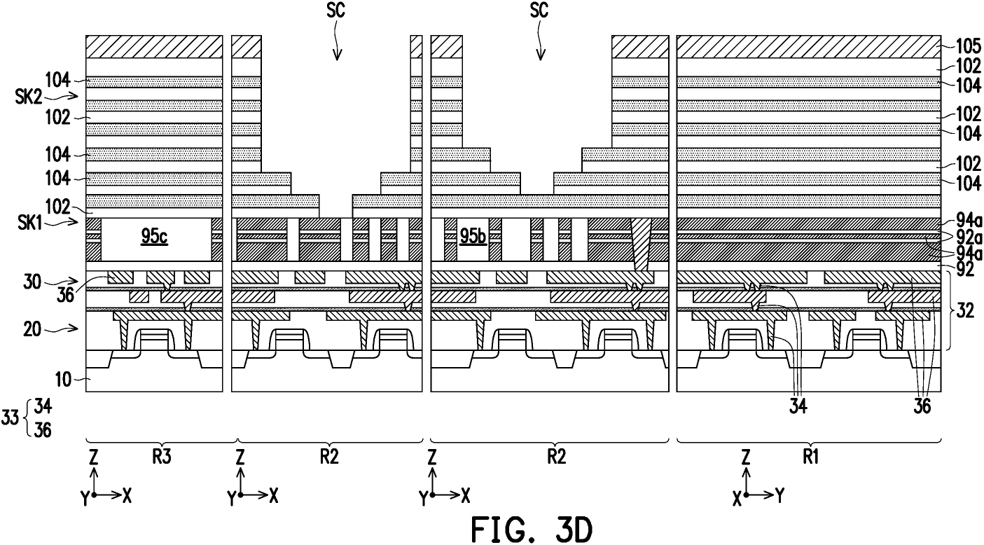

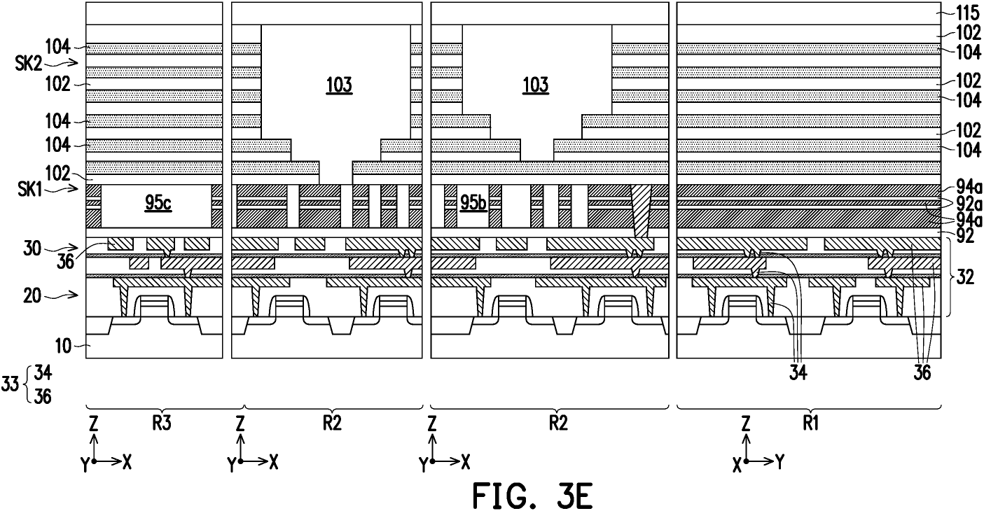

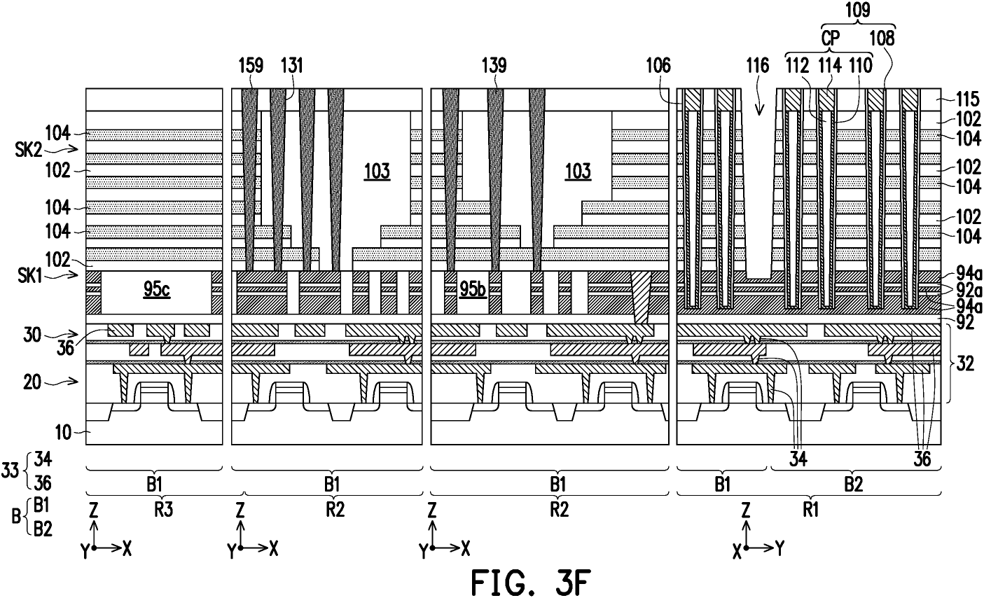

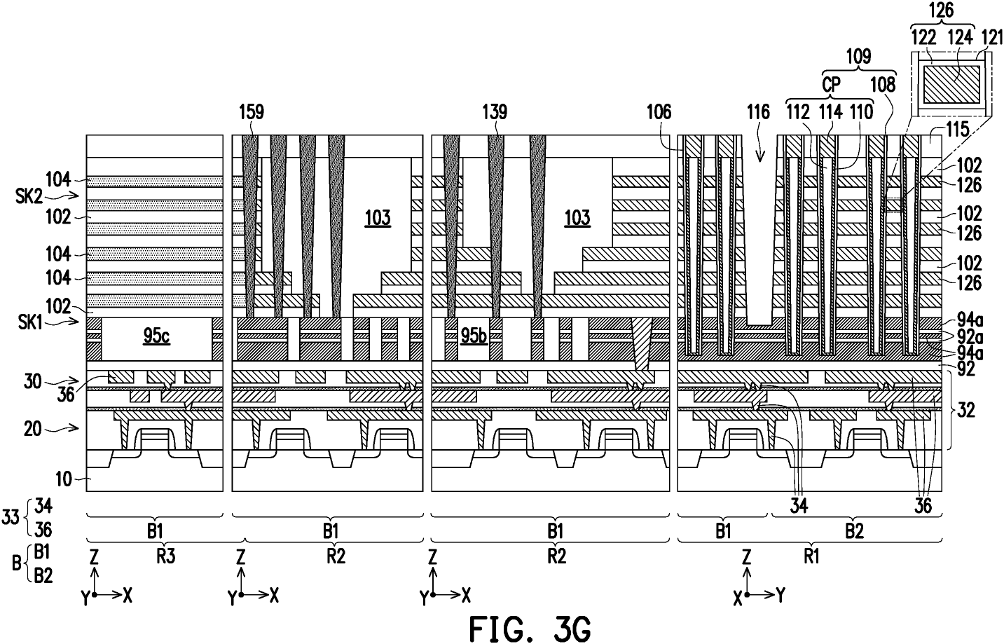

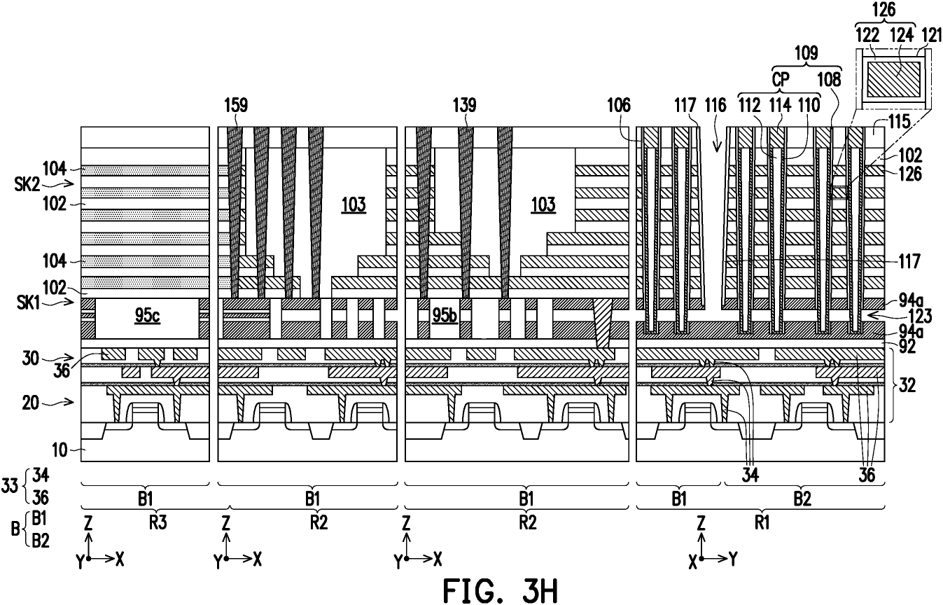

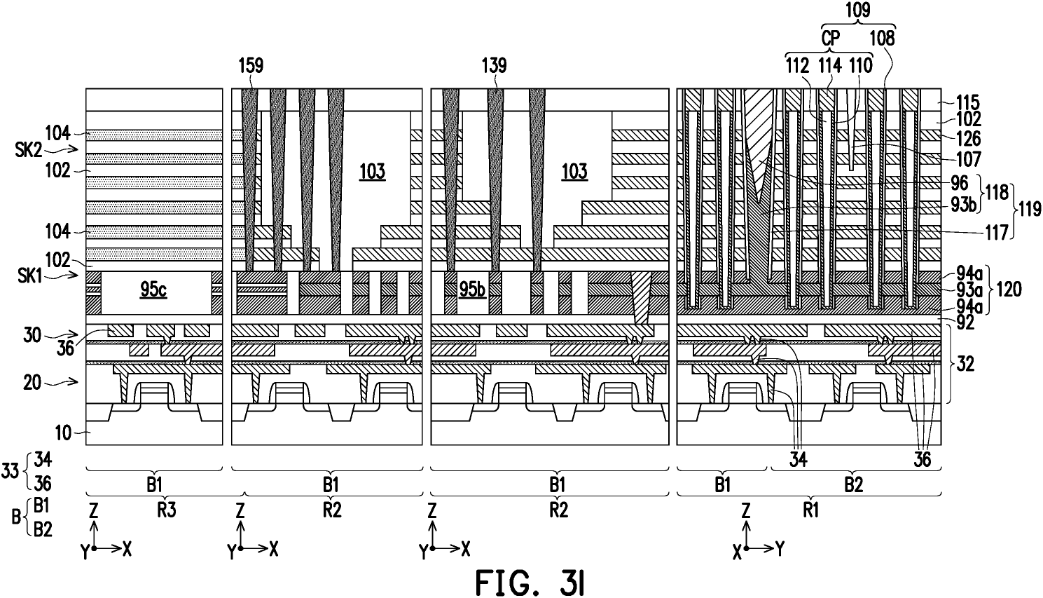

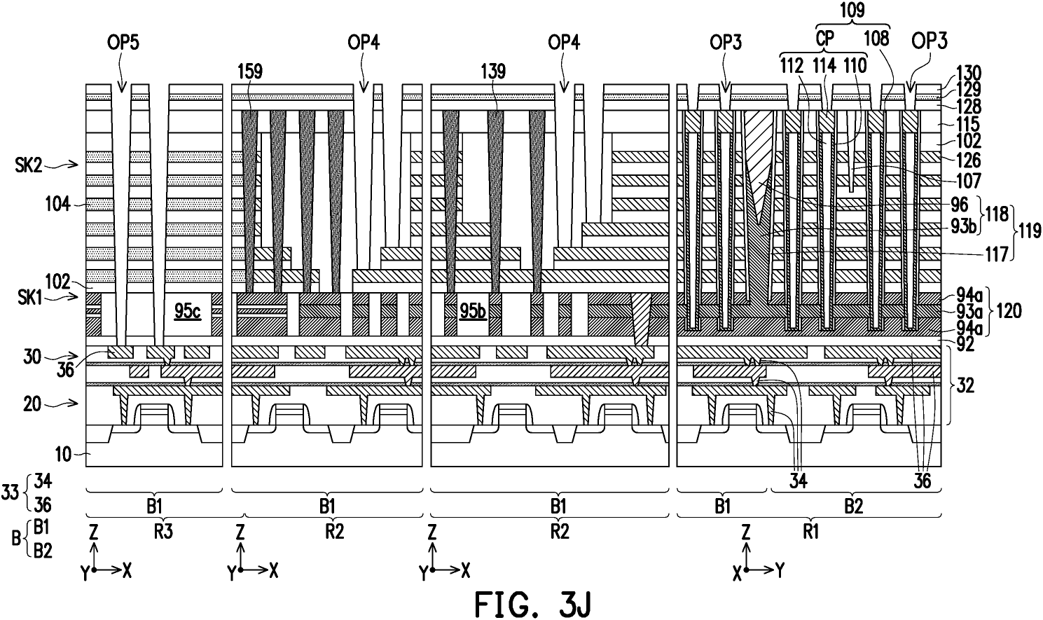

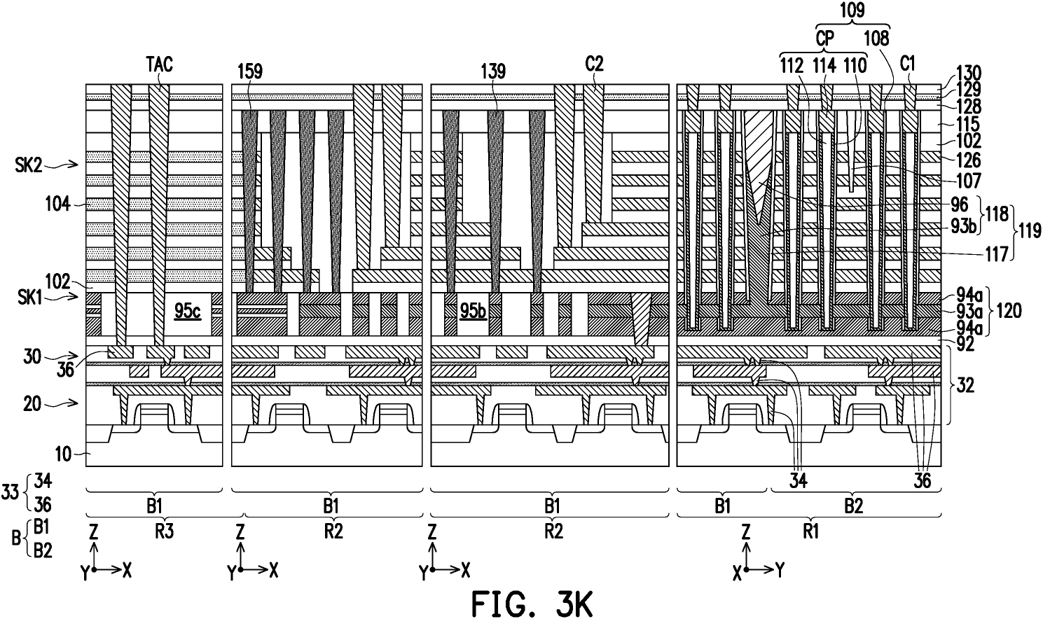

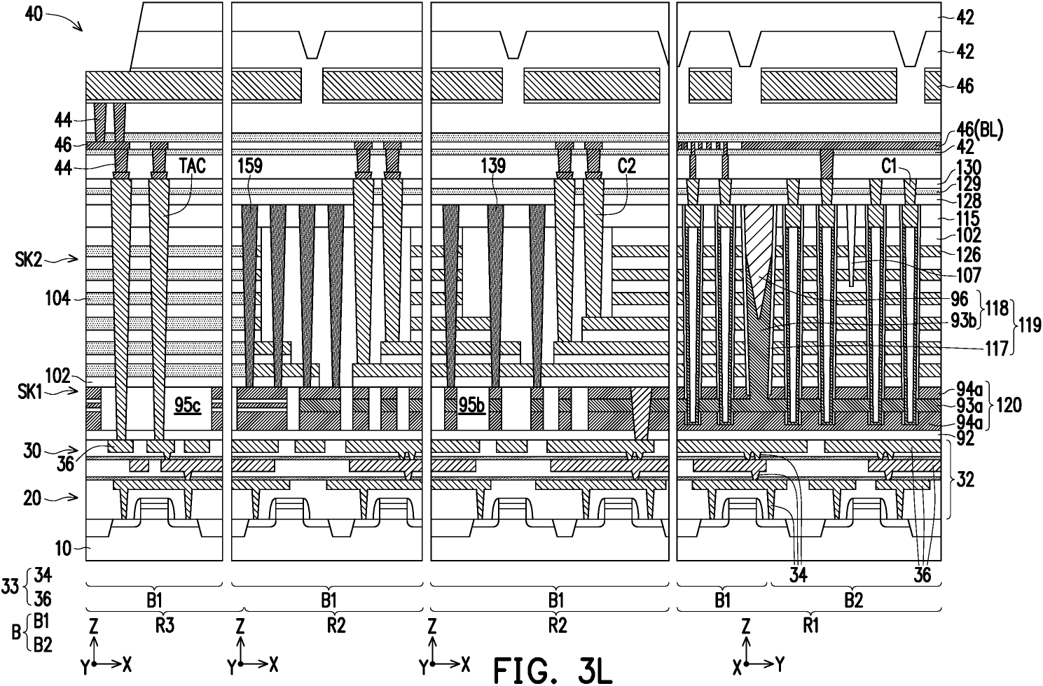

FIG. 2 is an enlarged top view of a partial region of FIG. 1B. FIG. 3A to FIG. 3L are schematic cross-sectional views showing a method of fabricating a three-dimensional memory device according to an embodiment of the disclosure.

Referring to FIG. 2 and FIG. 3A, a substrate 10 is provided. The substrate 10 includes a first region R1, a second region R2, and a third region R3. The first region R1, the second region R2, and the third region R3 may also be referred to as a memory array region R1, a staircase region R2, and an isolation region R3. The substrate 10 may be a semiconductor substrate, such as a silicon-containing substrate.

Referring to FIG. 3A, a device layer 20 is formed on the substrate 10. The device layer 20 may include an active device or a passive device. The active device is, for example, a transistor, a diode, etc. The passive device is, for example, a capacitor, an inductor, etc. The transistor may be an N-type metal-oxide-semiconductor (NMOS) transistor, a P-type metal-oxide-semiconductor (PMOS) transistor, or a complementary metal-oxide-semiconductor (CMOS).

Referring to FIG. 3A, a metal interconnect structure 30 is formed on the device layer 20. The metal interconnect structure 30 may include a plurality of dielectric layers 32 and a metal interconnect 33 formed in the dielectric layers 32. The metal interconnect 33 includes a plurality of plugs 34, a plurality of conductive lines 36, etc. The dielectric layer 32 separates adjacent conductive lines 36. The conductive lines 36 may be connected to each other through the plug 34, and the conductive lines 36 may be connected to the device layer 20 through the plugs 34.

Referring to FIG. 3A, an interlayer structure SK1 is formed on the metal interconnect structure 30. The interlayer structure SK1 includes a plurality of insulating layers 92 and a plurality of conductive layers 94 stacked alternately on each other along the Z direction. In an embodiment, the material of the insulating layer 92 includes silicon oxide, and the material of the conductive layer 94 includes doped polysilicon. The numbers of the insulating layers 92 and the conductive layers 94 are not limited to those shown in the figures. Since a memory array is to be formed directly above the interlayer structure SK1 in the first region R1, and the device layer 20 such as a complementary metal-oxide-semiconductor (CMOS) is to be formed below the memory array, this configuration may also be referred to as a CMOS-Under-Array (CUA) structure.

Referring to FIG. 3B, insulating structures 95b and insulating bulks 95c are formed in the interlayer structure SK1. The insulating structures 95b are formed in the first region R1 and the second region R2, and the insulating bulks 95c are formed in the third region R3, as shown in FIG. 2. In some embodiments, the method of forming the insulating structures 95b and the insulating bulks 95c includes the following steps. The interlayer structure SK1 is patterned to form a patterned conductive layer 94a and a patterned insulating layer 92a. The patterned conductive layer 94a has grooves 111b in the first region R1 and the second region R2, and has a groove 111c in the third region R3. An insulating material (e.g., silicon oxide) is filled in the grooves 111b and 111c, and then, a chemical-mechanical planarization process is performed to remove the excessive insulating material and form insulating structures 95b in the grooves 111b and insulating bulks 95c in the grooves 111c. The insulating structure 95b and the insulating bulks 95c may be in the shape of islands. The top view of the island may be round, oval, square with rounded corners or rectangle with rounded corners.

Referring to FIG. 3C, a plurality of insulating layers 102 and a plurality of middle layers 104 are alternately stacked above the interlayer structure SK1, to form an interlayer structure SK2. In an embodiment, the material of the insulating layer 102 includes silicon oxide, and the material of the middle layer 104 includes silicon nitride. The middle layers 104 may serve as sacrificial layers and may be partially or completely removed in a subsequent process. Then, a stop layer 105 is formed on the interlayer structure SK2. The material of the stop layer 105 is different from the materials of the insulating layer 102 and the middle layer 104, and is, for example, polysilicon. In some embodiments, the insulating layers 102 and the middle layers 104 are also referred to as first insulating layers 102 and second insulating layers 104.

Referring to FIG. 3D, the middle layer 104 and the insulating layer 102 of the interlayer structure SK2 in the second region R2 are patterned to form a staircase structure SC. In some embodiments, the staircase structure SC may be formed through a multi-step patterning process, but the disclosure is not limited thereto. The patterning process may include processes such as lithography, etching, and trimming.

Referring to FIG. 3E, a dielectric layer 103 is formed on the substrate 10 to cover the staircase structure SC. The material of the dielectric layer 103 is, for example, silicon oxide. The method of forming the dielectric layer 103 includes, for example, forming a dielectric material layer to fill and cover the staircase structure SC. Afterwards, by using the stop layer 105 as a polishing stop layer, a planarization process such as a chemical-mechanical polishing process is performed to remove the dielectric material layer on the stop layer 105. Next, the stop layer 105 is removed. An insulating cap layer 115 is formed on the interlayer structure SK2. In an embodiment, the material of the insulating cap layer 115 includes silicon oxide.

Referring to FIG. 3F, a patterning process is performed to remove portions of the insulating cap layer 115, the interlayer structure SK2, and the interlayer structure SK1 in the first region R1, to form one or more openings 106 penetrating through the insulating cap layer 115, the interlayer structure SK2, and the interlayer structure SK1. In an embodiment, the opening 106 may have a slightly inclined sidewall, as shown in FIG. 3F. In another embodiment, the opening 106 may have a substantially vertical sidewall (not shown). In an embodiment, the opening 106 is also referred to as a vertical channel (VC) opening. In an embodiment, the opening 106 may be formed through single-step lithography and etching processes. In another embodiment, the opening 106 may be formed through multi-step lithography and etching processes. The contour of the sidewall of the opening 106 formed through the multi-step lithography and etching processes may be in a segmental shape, for example. Next, a vertical channel pillar CP is formed in the opening 106. The vertical channel pillar CP may be formed by the following steps.

Referring to FIG. 3F again, a charge storage structure 108 is formed on the sidewall of the opening 106. The charge storage structure 108 is in contact with the insulating cap layer 115, the insulating layers 102, the middle layers 104, the patterned insulating layers 92a, and the patterned conductive layers 94a. In an embodiment, the charge storage structure 108 is an oxide/nitride/oxide (ONO) composite layer. The charge storage structure 108 is formed on the sidewall of the opening 106 in the form of a spacer and exposes the bottom surface of the opening 106.

Next, referring to FIG. 3F again, a channel layer 110 is formed on the charge storage structure 108. In an embodiment, the material of the channel layer 110 includes polysilicon. In an embodiment, the channel layer 110 covers the charge storage structure 108 on the sidewall of the opening 106 and also covers the bottom surface of the opening 106. Next, an insulating pillar 112 is formed at the lower portion of the opening 106. In an embodiment, the material of the insulating pillar 112 includes silicon oxide. Afterwards, a conductive plug 114 is formed at the upper portion of the opening 106, and the conductive plug 114 is in contact with the channel layer 110. In an embodiment, the material of the conductive plug 114 includes polysilicon. The channel layer 110, the insulating pillar 112, and the conductive plug 114 may be collectively referred to as a vertical channel pillar CP. The charge storage structure 108 and the vertical channel pillar CP may be collectively referred to as a pillar structure 109.

Then, referring to FIG. 2 and FIG. 3F, in some embodiments, the support pillar 139 may also be formed simultaneously with the pillar structure 109 in the second region R2, so as to prevent collapse of the staircase structure SC in a subsequent removal process of the middle layers 104. The support pillar 139 may have the same configuration (not shown) as the pillar structure 109, but the disclosure is not limited thereto. In other embodiments, the support pillar 139 may be formed separately from the pillar structure 109, and the configuration and material thereof may be different from those of the pillar structure 109. For example, the material of the support pillar 139 may include silicon oxide. The support pillar 139 may be formed by performing a patterning process to remove portions of the insulating cap layer 115, the interlayer structure SK2 and the interlayer structure SK1 in the first region R1 and the second region R2, so as to form a plurality of openings 131 penetrating through the insulating cap layer 115, the interlayer structure SK2 and the interlayer structure SK1. The shape and forming method of the openings 131 may be the same as, similar or different to the shape and forming method of the openings 106. In other embodiments, the opening 131 and the opening 106 have different shapes. Afterwards, a support material is filled in the openings 131.

After that, referring to FIG. 2 and FIG. 3F, in some embodiments, during the formation of the pillar structures 109, portions of the insulating cap layer 115, the interlayer structure SK2 and the interlayer structure SK1 may be removed simultaneously, to form insulating slits 149 and 159. The insulating slit 149 (shown in FIG. 2) is located at the end of a selective source line cut slit 107 and is connected to the selective source line cut slit 107. The insulating slit 159 (shown in FIG. 2) is a closed pattern surrounding the third region R3 and lands on a source line 120 (i.e., on patterned conductive layers 94a and 92a) of the interlayer structure SK1.

Referring to FIG. 3F again, a patterning process is performed on the interlayer structure SK2 to form a plurality of trenches 116. The trench 116 extends in the X direction and penetrates through the insulating cap layer 115 and the interlayer structure SK2 to divide the interlayer structure SK2 into a plurality of blocks B (e.g., blocks B1 and B2). In an embodiment, the trench 116 may have a slightly inclined sidewall, as shown in FIG. 3F. In another embodiment, the trench 116 may have a substantially vertical sidewall (not shown). The trench 116 exposes the sidewalls of the insulating cap layer 115, the middle layers 104, and the insulating layers 102.

Referring to FIG. 3G, afterwards, a replacement process is performed to replace the middle layers 104 in the first region R1 and the second region R2 with conductive layers 126. First, a selective etching process is performed, so that an etchant flows into the trench 116 to be in contact with the interlayer structure SK2 at two sides of the trench 116. Accordingly, the middle layers 104 in the first region R1 and the second region R2 are removed to form a plurality of horizontal openings 121. The horizontal opening 121 exposes a portion of the charge storage structure 108, the upper and lower surfaces of the insulating layers 102, and the sidewall of the dielectric layer 103 in the first region R1, and exposes the sidewall of a portion of the support pillar (not shown). The selective etching process may be an isotropic etching such as a wet etching process. The etchant used in the wet etching process is, for example, a hot phosphoric acid. The middle layers 104 in the third region R3 are shielded by the dielectric layer 103 and thus are retained without being removed.

Referring to FIG. 3G, then, a conductive layer 126 is formed in the trench 116 and the horizontal opening 121. The conductive layer 126 may serve as a gate layer. The conductive layer 126 includes, for example, a barrier layer 122 and a metal layer 124. In an embodiment, the material of the barrier layer 122 includes titanium (Ti), titanium nitride (TiN), tantalum (Ta), tantalum nitride (TaN), or a combination thereof, and the material of the metal layer 124 includes tungsten (W).

Referring to FIG. 3H and FIG. 3I, next, a spacer 117 is formed on the sidewall of the trench 116. The spacer 117 includes a dielectric material different from the material of the insulating layer 102, and the dielectric material may be silicon nitride or a silicon oxide/silicon nitride/silicon oxide composite layer. Afterwards, the trench 116 is deepened, the middle one of the patterned conductive layers 94a of the interlayer structure SK1 in the first region R1 and the second region R2 is removed, and the insulating layers 92a on and below the patterned conductive layer 94a are removed. Thus, a horizontal opening 123 is formed in the interlayer structure SK1, and the charge storage structure 108 exposed by the opening 108 is removed. Then, a conductive layer such as a doped polysilicon layer is filled in the trench 116 and the horizontal opening 123. The conductive layer 93a in the horizontal opening 123 and the patterned conductive layers 94a on and below the conductive layer 93a collectively form a source line 120. After the source line 120 is formed, the conductive layer in the trench 116 is etched back to form a conductive layer 93b, and a groove is formed on the conductive layer 93b. Next, a conductive pad 96 is formed in the groove on the conductive layer 93b. The material of the conductive pad 96 is, for example, tungsten. The conductive pad 96 and the conductive layer 93b collectively form a source line slit 118 for conducting the current from the source line 120. The source line slit 118 is insulated from the conductive layers 126 by the spacer 117, and thus the source line slit 118 is not in contact with the conductive layers 126. The source line slit 118 and the spacer 117 may be collectively referred to as a slit structure 119.

Referring to FIG. 3I, a selective source line cut slit 107 extending in the X direction is formed in portions of the insulating cap layer 115 and the interlayer structure SK2 in each block B. The selective source line cut slit 107 includes an insulating material such as silicon oxide, and the selective source line cut slit 107 separates the upper conductive layers 126 of the interlayer structure SK2 in each block B from one another. The selective source line cut slit 107 may be formed at any stage of the fabricating process. For example, the selective source line cut slit 107 is formed previously such as before the formation of the staircase structure SC.

Referring to FIG. 3J, next, a dielectric layer 128, a stop layer 129, and a dielectric layer 130 are formed on the insulating cap layer 115. The dielectric layers 128 and 130 include silicon oxide, and the stop layer 129 includes silicon nitride, for example. Afterwards, lithography and etching processes are performed to form contact openings OP3, OP4, and OP5 in the first region R1, the second region R2, and the third region R3 respectively. The contact opening OP3 penetrates through the dielectric layer 130, the stop layer 129 and the dielectric layer 128 to expose the conductive plug 114 of the vertical channel pillar CP. The contact opening OP4 penetrates through the dielectric layer 130 and extends into the dielectric layer 103, to expose the top surface of the conductive layer 126 of the staircase structure SC. The contact opening OP5 penetrates through the dielectric layer 130 and extends into the interlayer structure SK2 and the insulating bulk 95c, to expose the top surface of the conductive line 36.

Referring to FIG. 3K, next, contacts C1, C2, and TAC are formed in the contact openings OP3, OP4, and OP5 respectively. The contact C1 lands on the conductive plug 114 of the vertical channel pillar CP and is electrically connected to the conductive plug 114. The contact C2 penetrates through the dielectric layer 103, lands on the surface of the end of the conductive layer 126 of the staircase structure SC, and is electrically connected to the conductive layer 126. The contact TAC may also be referred to as a through array contact. The contact TAC penetrates through the dielectric layer 130 and extends into the insulating cap layer 115, the interlayer structure SK2 and the insulating block 95c. The contact TAC lands on the surface of the conductive line 36 and is electrically connected to the conductive line 36. In an embodiment, each of the contacts C1, C2 and TAC may include a barrier layer and a conductive layer. The material of the barrier layer is, for example, titanium (Ti), titanium nitride (TiN), tantalum (Ta), tantalum nitride (TaN), or a combination thereof, and the material of the conductive layer is, for example, tungsten (W). The method of forming the contacts C2 and TAC includes, for example, sequentially forming a barrier layer and a conductive layer on the dielectric layer 130 and in the contact openings OP3, OP4 and OP5, and then performing a planarization process by a chemical-mechanical polishing method.

Referring to FIG. 3L, a metal interconnect structure 40 is formed. The metal interconnect structure 40 may include a plurality of dielectric layers 42 and a plurality of plugs 44, a plurality of conductive lines 46, etc., formed in the dielectric layers 42. The dielectric layer 42 separates adjacent conductive lines 46. The conductive lines 46 may be connected to each other through the plug 44, and the conductive lines 46 may be respectively electrically connected to the contacts C1, C2, and TAC. The conductive line 46 connected to the contact C1 may serve as a bit line BL.

Afterwards, subsequent fabrication processes are performed to complete the fabrication of the memory device.

Referring to FIG. 1B to FIG. 1J, in an embodiment of the disclosure, the stress caused by the slit structure 119 may be dispersed or reduced by the arrangement of the assistance structures 199, so that the stress distributed in various directions (such as the X direction and the Y direction) is more even. Accordingly, issues such as asymmetric wafer warpage is avoided or reduced. For example, the assistance structures 199 may include slits extending along the Y direction, to disperse or reduce the stress caused by the slit structure 119 extending in the X direction.

Referring to FIG. 1B to FIG. 1J, the composition, shape and size of the assistance structures 199 may be the same, similar or different. Each assistance structure 199 may be the same as or similar to the components in some regions of the block region.

Referring to FIG. 2, for example, the assistance structure 199 may be similar to some components in the region 10A, the region 10B, and the region 10C of the block region. The assistance structure 199 may be the same as or similar to the slit structure 119, the pillar structure 109, the insulating structure 95b, and the support pillar 139.

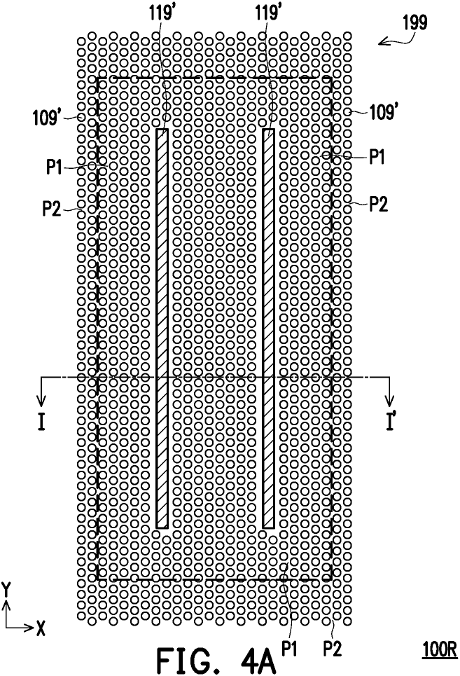

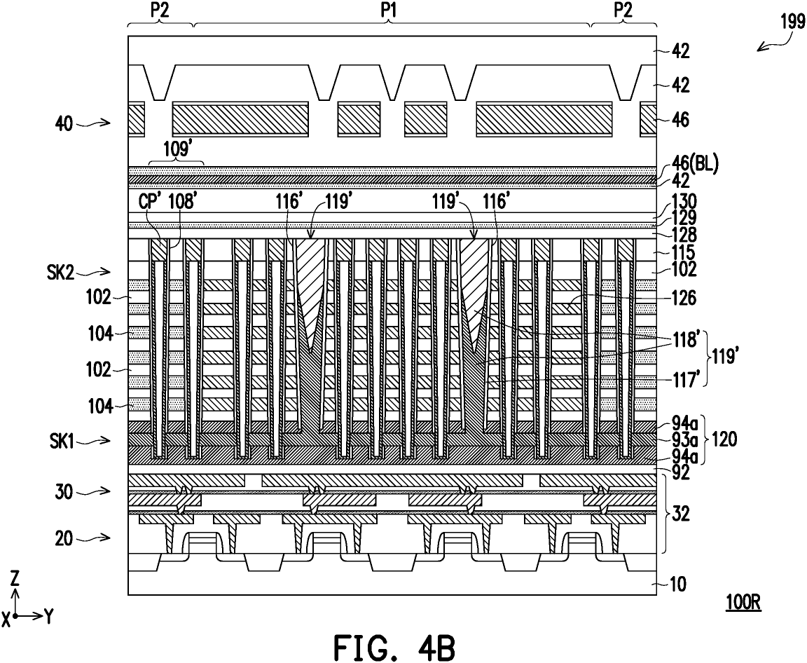

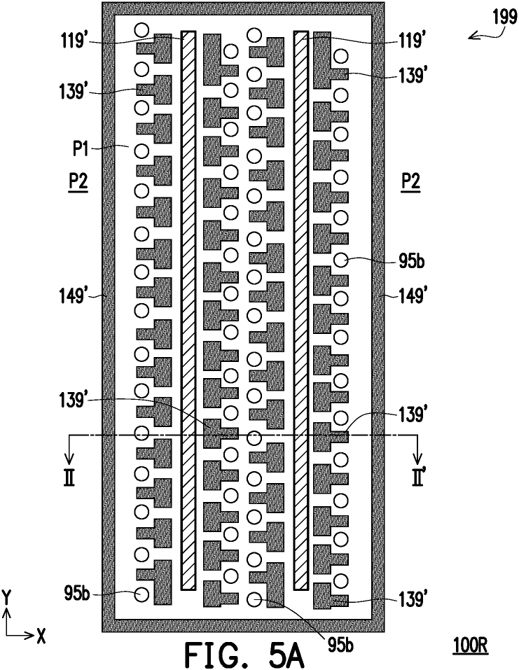

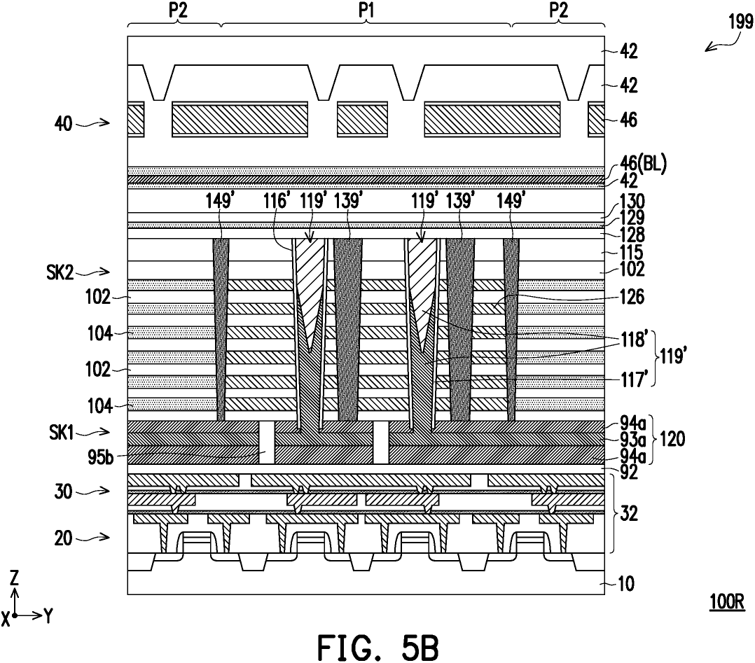

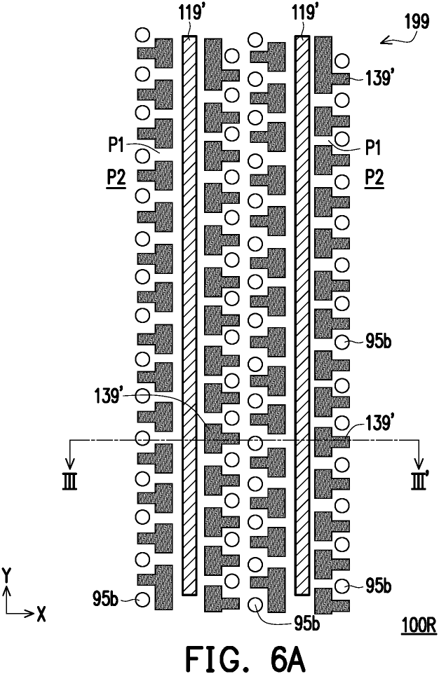

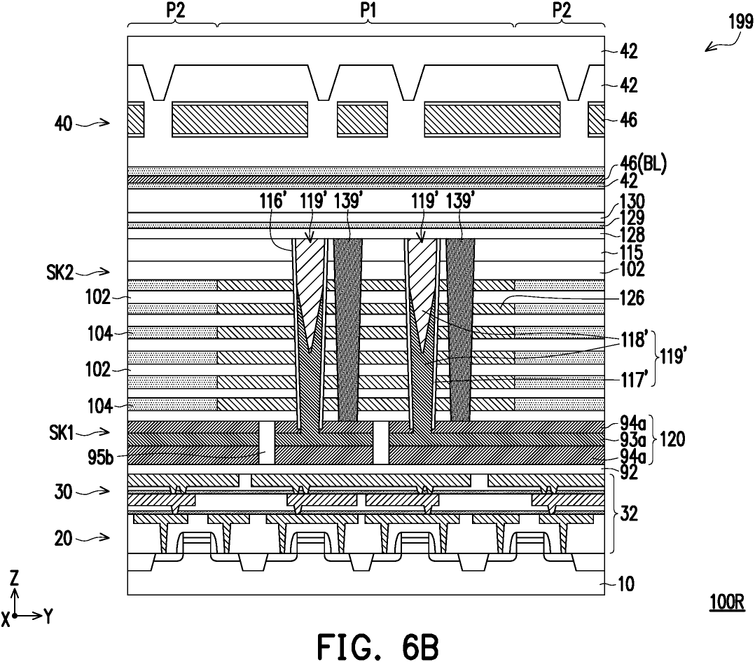

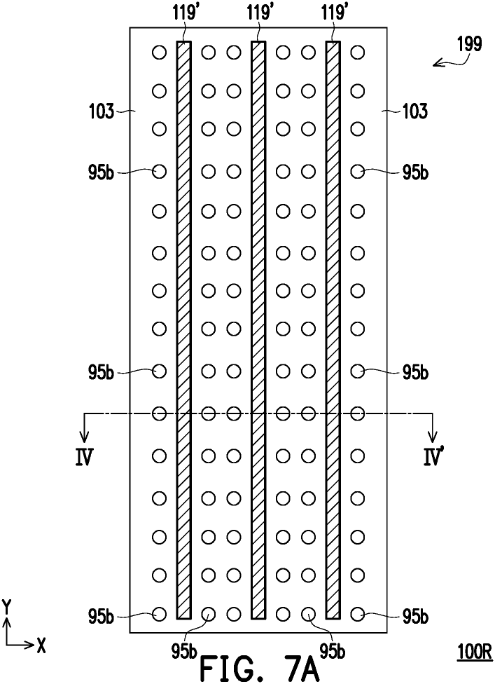

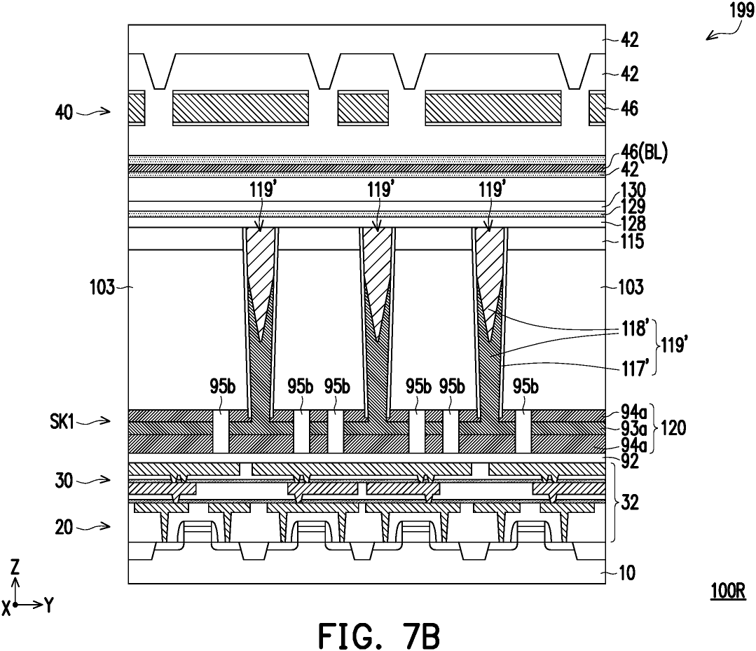

FIG. 4A to FIG. 7B are partial top and cross-sectional views showing iso regions of several three-dimensional memory devices according to multiple embodiments of the disclosure. FIG. 4B is a cross-sectional view taken along a line I-I′ of FIG. 4A. FIG. 5B is a cross-sectional view taken along a line II-II′ of FIG. 5A. FIG. 6B is a cross-sectional view taken along a line III-III′ of FIG. 6A. FIG. 7B is a cross-sectional view taken along a line IV-IV′ of FIG. 7A.

Referring to FIG. 3L and FIG. 4A to FIG. 7B, the assistance structure 199 includes a dummy slit structure 119′. The number of the dummy slit structures 119′ may be determined according to the size of the iso region 100R. There may be a single dummy slit structure 119′ if the size of the iso region 100R. On contrary, if the size of the iso region 100R is large, a plurality of dummy slit structures 119′ may be provided. The extending direction of each dummy slit structure 119′ is different from the extending direction of the slit structure 119. In some embodiments, the slit structures 119 extend in the X direction (shown in FIG. 1A and FIG. 2), and the dummy slit structures 119′ extend in the Y direction (shown in FIG. 4A). The dummy slit structure 119′ may include the same components as the slit structure 119. The dummy slit structure 119′ may include a dummy slit 118′ and a dummy spacer 117′. The material, shape and size of the dummy slit 118′ and the dummy spacer 117′ may be the same or similar to those of the source line slit 118 and the spacer 117, respectively. The bottom of the dummy slit 118′ may be electrically connected to the source line 120. The top surface of the dummy slit 118′ may be covered by the dielectric layer 128.

Referring to FIG. 4A and FIG. 4B, the assistance structure 199 may include a plurality of dummy slit structures 119′ and a plurality of dummy pillar structures 109′. The dummy slit structures 119′ are the same as or similar to the slit structures 119 (shown in FIG. 3L) in the region 10A of FIG. 2. The dummy slit structures 119′ extend through the interlayer structure SK2 and are electrically connected to the source line 120. The dummy slit structures 119′ may be formed simultaneously with the slit structures 119.

Referring to FIG. 4A and FIG. 4B, the dummy pillar structures 109′ are respectively the same as or similar to the pillar structures 109 in the region 10A of FIG. 2. The dummy pillar structures 109′ may be formed simultaneously with the pillar structures 109. Referring to FIG. 4A, the dummy pillar structures 109′ of the assistance structure 199 surround the dummy slit structure 119′. Referring to FIG. 4B, each of the dummy pillar structures 109′ may include a dummy vertical channel pillar CP′ and a dummy charge storage structure 108′. The dummy charge storage structure 108′ surrounds the outer surface of the dummy vertical channel pillar CP′. The materials and forming methods of the dummy vertical channel pillar CP′ and the dummy charge storage structure 108′ may be the same or similar to those of the vertical channel pillar CP and the charge storage structure 108. The pillar structures 109′ penetrate through the interlayer structure SK2 and are electrically connected to the source line 120. The pillar structures 109′ are not connected to the upper bit line.

Referring to FIG. 4A and FIG. 4B, the interlayer structure SK2 may include a first portion P1 and a second portion P2 in the iso region 100R. The first portion P1 is connected to the second portion P2. The first portion P1 is closer to the dummy slit structure 119′ than the second portion P2. The first portion P1 is extended through by the dummy slit structures 119′ and portions of the pillar structures 109′. The first portion P1 includes a plurality of first insulating layers 102 and a plurality of gate conductive layers 126 stacked alternately with each other. The second portion P2 is extended through by other portions of pillar structures 109′. The second portion P2 includes the first insulating layers 102 and a plurality of second insulating layers 104 stacked alternately with each other. The difference between the first portion P1 and the second portion P2 is because during the formation of the dummy slit structures 119′, portions of the second insulating layers 104 adjacent to the dummy trenches 116′ (used for forming the dummy slit structures 119′) are removed and then replaced with the gate conductive layers 126. Therefore, the interlayer structure SK2 around the dummy slit structures 119′ includes the first portion P1 and the second portion P2.

Referring to FIG. 5A and FIG. 5B, the assistance structure 199 may include a plurality of dummy slit structures 119′, a plurality of dummy support pillars 139′ and a dummy insulating slit 149′. The dummy slit structures 119′ are the same as or similar to the slit structures 119 in the region 10B of FIG. 2. The dummy slit structures 119′ penetrate through the interlayer structure SK2 and are electrically connected to the source line 120 of the interlayer structure SK1.

Referring to FIG. 5A and FIG. 5B, the dummy support pillars 139′ are respectively the same as or similar to the support pillars 139 in the region 10B of FIG. 2. Referring to FIG. 5A, the dummy support pillars 139′ are disposed on both sides of each dummy slit structure 119′. Referring to FIG. 5B, the dummy slit structures 119′ land on the source line 120 (i.e., the patterned conductive layers 94a) of the interlayer structure SK1.

Referring to FIG. 5A, the dummy insulating slit 149′ is a closed pattern surrounding the dummy slit structures 119′ and the dummy support pillars 139′. Referring to FIG. 5B, the dummy insulating slit 149′ penetrates through the interlayer structure SK2 and lands on the source line 120 (i.e., the patterned conductive layers 94a) of the interlayer structure SK1.

Referring to FIG. 5B, the interlayer structure SK2 is extended through by the dummy insulating slit 149′, and thus is divided into a first portion P1 and a second portion P2. That is, the first portion P1 and the second portion P2 are separated by the dummy insulating slit 149′ and are not connected, as shown in FIG. 5B. The first portion P1 is closer to the dummy slit structure 119′ than the second portion P2. The first portion P1 is extended through by the dummy slit structures 119′ and a portion of the dummy support pillars 139′. The first portion P1 includes a plurality of first insulating layers 102 and a plurality of gate conductive layers 126 stacked alternately with each other. The second portion P2 includes the first insulating layers 102 and a plurality of second insulating layers 104 stacked alternately with each other. The difference between the first portion P1 and the second portion P2 is because during the formation of the dummy slit structures 119′, portions of the second insulating layers 104 between the dummy insulating slit 149′ and the dummy trench 116′ (used for forming the dummy slit structure 119′) are removed and then replaced with the gate conductive layers 126. On contrary, the second insulating layers 104 away from the dummy trenches 116′ are shielded by the dummy insulating slit 149′ and are thus retained. Therefore, the interlayer structure SK2 around the dummy slit structures 119′ includes the first portion P1 and the second portion P2.

Referring to FIG. 5A and FIG. 5B, the insulating structures 95b of the interlayer structure SK1 are embedded in the source line 120 (i.e., the patterned conductive layers 94a and 93a), as shown in FIG. 5B. The insulating structure 95b is disposed around the dummy slit structure 119′, as shown in FIG. 5A. The dummy support pillars 139′ are located between the dummy slit structures 119′ and between the insulating structure 95b, as shown in FIG. 5A.

Referring to FIG. 6A and FIG. 6B in some embodiments, the assistance structure 199 may include a plurality of dummy slit structures 119′ and a plurality of dummy support pillars 139′, in which the dummy insulating slits 149′ (shown in FIG. 5A and FIG. 5B) are omitted. Similarly, during the formation of the dummy slit structures 119′, portions of the second insulating layers 104 adjacent to the dummy trenches 116′ (used for forming the dummy slit structures 119′) are removed and then replaced with the gate conductive layers 126. Therefore, the interlayer structure SK2 in the iso region 100R also includes the first portion P1 and the second portion P2 which are connected to each other.

Referring to FIG. 7A and FIG. 7B, the assistance structure 199 may include a plurality of dummy slit structures 119′. Referring to FIG. 7B, in some embodiments, in the iso region 100R, the dielectric layer 103 instead of the interlayer structure SK2 is disposed above the interlayer structure SK1. The dummy slit structure 119′ extends through the dielectric layer 103, is landed on the source line 120 (i.e., the patterned conductive layers 94a) of the interlayer structure SK1, and is electrically connected to the source line 120. Referring to FIG. 7A, the insulating structures 95b in the interlayer structure SK1 are disposed at two sides or around the dummy slit structures 119′.

In the embodiment of the disclosure, by disposing a plurality of assistance structures, the stress caused by the slit structure extended in a single direction may be reduced, so as to disperse or reduce uneven stress distribution of the chip. Accordingly, the issues such as asymmetric wafer warpage caused by uneven stress and avoid abnormal tool operation in subsequent processes.______

The assistance structure may be formed simultaneously with the fabricating process of the memory device, and thus no additional process is needed.

What is claimed is:

1. A memory device, comprising:
a dielectric substrate, comprising an array region and an iso region aside the array region;
an interlayer structure in the array region and the iso region;
a plurality of channel pillars, penetrating through the interlayer structure in the array region;
a plurality of charge storage structures between the interlayer structure and the plurality of channel pillars;
a plurality of slit structures between the plurality of channel pillars, penetrating through the interlayer structure in the array region, and dividing the interlayer structure into a plurality of blocks; and
an assistance structure in the iso region, wherein the assistance structure comprises at least one dummy slit structure, and an extension direction of the at least one dummy slit structure is different from an extension direction of the plurality of slit structures.

2. The memory device of claim 1, wherein the at least one dummy slit structure, penetrating downwardly through the interlayer structure in the iso region, wherein the plurality of slit structures extend in a first direction, and the at least one dummy slit structure extends in a second direction different from the first direction different.

3. The memory device of claim 2, wherein the assistance structure further comprises:
a plurality of dummy pillar structures, penetrating through the interlayer structure in the iso region, wherein the plurality of dummy pillar structures are arranged around the at least one dummy slit structure.

4. The memory device of claim 3, wherein the interlayer structure in the iso region comprises:
a first portion, comprising a plurality of first insulating layers and a plurality of gate conductive layers stacked alternately with each other; and
a second portion, comprising the plurality of first insulating layers and a plurality of second insulating layers stacked alternately with each other,
wherein the first portion is closer to the at least one dummy slit structure than the second portion.

5. The memory device of claim 3, further comprising:
a patterned conductive layer, disposed in the array region between the dielectric substrate and the interlayer structure in the iso region, wherein the plurality of slit structures and the at least one dummy slit structure land on the patterned conductive layer; and
a plurality of insulating structures, embedded in the patterned conductive layer in the array region and disposed around the plurality of slit structures, and embedded in the patterned conductive layer in the iso region and disposed around the at least one dummy slit structure.

6. The memory device of claim 5, further comprising:
a plurality of support pillars, extending through the interlayer structure in the array region, being arranged between the plurality of insulating structures and the plurality of slit structures, and landing on the patterned conductive layer,
wherein the assistance structure further comprises:
a plurality of dummy support pillars, extending through the interlayer structure in the iso region, being arranged between the plurality of insulating structures and the plurality of dummy slit structures, and landing on the patterned conductive layer.

7. The memory device of claim 6, wherein the interlayer structure in the iso region comprises:
a first portion, comprising a plurality of first insulating layers and a plurality of gate conductive layers stacked alternately with each other; and
a second portion, comprising the plurality of first insulating layers and a plurality of second insulating layers stacked alternately with each other,
wherein the first portion is closer to the at least one dummy slit structure than the second portion.

8. The memory device of claim 7, wherein the assistance structure further comprises:
a dummy insulating slit, surrounding the at least one dummy slit structure and the plurality of dummy support pillars, penetrating through the interlayer structure in the iso region, and landing on the patterned conductive layer,
wherein the first portion is located inside the dummy insulating slit, and the second portion is located outside the dummy insulating slit.

9. The memory device of claim 5, wherein the inter structure comprises:
a dielectric layer, located on the patterned conductive layer in the iso region,
wherein the at least one dummy slit structure further penetrates through the dielectric layer in the iso region and lands on the patterned conductive layer.

10. The memory device of claim 1, wherein the iso region comprises a scribe region, a seal ring region or a boundary region.

11. The memory device of claim 1, wherein the dielectric substrate comprises a plurality of chip regions, and each chip region has the plurality of assistance structures.

12. The memory device of claim 11, wherein the plurality of assistance structures in the same chip region are the same or different.

13. The memory device of claim 11, wherein the plurality of assistance structures in different chip regions are the same or different.

14. A method of fabricating a memory device, comprising:
forming an interlayer structure in an array region and an iso region of a dielectric substrate;
forming a plurality of channel pillars to penetrate through the interlayer structure in the array region;
performing a replacement process to replace a plurality of insulating layers of the interlayer structure with a plurality of gate conductive layers;
forming a plurality of slit structures between the plurality of channel pillars, wherein the plurality of slit structures extend through the interlayer structure in the array region and divide the interlayer structure into a plurality of blocks; and
forming an assistance structure in the iso region, wherein the assistance structure comprises at least one dummy slit structure, and an extension direction of the at least one dummy slit structure is different from an extension direction of the plurality of slit structures.

15. The method of claim 14, wherein forming the assistance structure in the iso region comprises:
forming the at least one dummy slit structure in the iso region simultaneously with the plurality of slit structures, and wherein the plurality of slit structures extend in a first direction, and the plurality of dummy slit structures extend in a second direction different from the first direction.

16. The method of claim 15, wherein forming the assistance structure in the iso region further comprises:
forming a plurality of dummy channel pillars simultaneously with the plurality of channel pillars, wherein the plurality of dummy channel pillars penetrate through the interlayer structure in the iso region and are arranged around the at least one dummy slit structure.

17. The method of claim 15, further comprising:
forming a patterned conductive layer, wherein the patterned conductive layer is disposed in the array region between the dielectric substrate and the interlayer structure in the iso region, and the plurality of slit structures and the at least one dummy slit structure land on the patterned conductive layer; and
forming a plurality of insulating structures, wherein the plurality of insulating structures are embedded in the patterned conductive layer in the array region and disposed around the plurality of slit structures, and are embedded in the patterned conductive layer in the iso region layer and disposed around the at least one dummy slit structure.

18. The method of claim 17, further comprising:
forming a plurality of support pillars, the plurality of support pillars extending through the interlayer structure in the array region, being arranged between the plurality of insulating structures and the plurality of slit structures, and landing on the plurality of gate conductive layers,
wherein forming the assistance structure in the iso region further comprises:
forming a plurality of dummy support pillars simultaneously with the plurality of support pillars, the plurality of dummy support pillars arranged between the plurality of insulating structures and the plurality of dummy slit structures, wherein the plurality of support pillars extend through the interlayer structure in the iso region and land on the patterned conductive layer.

19. The method of claim 18, wherein forming the assistance structure in the iso region further comprises:
forming a dummy insulating slit simultaneously with the plurality of support pillars, wherein the dummy insulating slit surrounds the at least one dummy slit structure and the plurality of dummy support pillars, penetrates through the interlayer structure in the iso region, and lands on the patterned conductive layer.

20. The method of claim 17, further comprising:
forming a dielectric layer on the patterned conductive layer in the iso region, wherein the at least one dummy slit structure further penetrates through the dielectric layer in the iso region and lands on the patterned conductive layer,
wherein the plurality of insulating structures are further embedded in the patterned conductive layer in the iso region, and are located around the at least one dummy slit structure.
